(19) United States
(12) Patent Application Publication
(10) Pub. No.: US 2026/0114224 A1
(43) Pub. Date: Apr. 23, 2026

(54) LOCKING FRAME HOLDER AND WORKPIECE LOADER FOR WET CHEMICAL SEMICONDUCTOR PROCESSING

(71) Applicant: ASMPT NEXX, Inc., Billerica, MA (US)

(72) Inventors: Arthur KEIGLER, Billerica, MA (US); Daniel L. GOODMAN, Billerica, MA (US)

(21) Appl. No.: 18/921,364

(22) Filed: Oct. 21, 2024

(51) Int. Cl. H01L 21/673

(52) U.S. Cl. CPC H10P 72/1914; H10P 72/1911; H10P 72/1916; H10P 72/1922

(57) ABSTRACT

A workpiece holder and an apparatus for loading workpieces onto the holder for use in wet chemical semiconductor processing is described. The workpiece holder comprises two perimeter seal plates, electrical contact inserts and a locking plate. The perimeter seal plates provide force for both fluid sealing and electrical contact when the locking plate is in a locked position. The locking plate also functions as an electrical bus to provide current to the electrical contact inserts. The workpiece loader comprises a stage to insert or remove a workpiece from the workpiece holder. The loader also comprises vacuum chucks to position the perimeter seal plates prior to loading and to compress the perimeter seal plates during locking and unlocking.

### BACKGROUND AND PRIOR ART

This invention relates to methods and systems for wet chemical semiconductor processing such as cleaning, etching and electroplating of semiconductor substrates for advanced packaging or high-density-interconnect applications. More specifically, this invention relates to systems and methods for transport and protection of workpieces such as rectangular substrates for use in wet chemical processes including electro-chemical deposition.

Electro-chemical deposition is used as a manufacturing technique for the application of thin films to semiconductor substrates including semiconductor wafers and rectangular panels. Films can include copper, tin, nickel, cobalt-iron, indium and other metals. During electrochemical deposition current flows from an anode through a plating bath to the cathode. When a substrate is used as the cathode, metal can be deposited thereon.

Advanced packaging involves interconnection of components before applying traditional integrated circuit packaging processes. Advanced packaging allows multiple devices to be merged and packaged as a single electronic device. Rectangular substrate panels are one type of advanced packaging substrate which provide manufacturing and cost advantages, allowing large and complex systems to be built up on the panel substrate. Rectangular substrate panels are typically manufactured as organic laminates consisting of glass fiber reinforcement in an epoxy composite matrix, a composition similar to printed circuit boards.

High purity glass may also be used as a rectangular panel substrate base material and has important advantages over organic laminates. Advantages include dimensional stability and a thermal expansion coefficient similar to silicon, both of which are important for heterogeneous integration applications. Direct bonding of die to glass improves thermal performance compared with organic laminates. Pure glass as a panel substrate also permits the filling of through glass vias using electroplating.

Workpiece holders are used for transport of substrates through wet-processing tools. When used in electroplating tools, workpiece holders also provide electrical contact during electroplating. Electrical contact with the workpiece or substrate typically occurs on faces in an edge region where the holder's metal contacts are in physical contact with a metal seed layer on the workpiece face. The contacts may need to align with openings in patterned photoresist in order to make contact with the seed layer.

This contact area needs to be kept dry to avoid metal buildup on the contacts as well as seed deplating due to the formation of localized galvanic cells. Therefore, an important function of the holder is to seal the contact area, preventing electroplating solution from wetting the electrical contacts and seed layer.

Workpiece holders for wet-processing steps such as chemical etch, photoresist strip and cleaning must provide secure support of the substrate, typically in a vertical orientation in a wet chemical process module, with minimal physical contact to the workpiece so that the chemical deposition or removal processes are not blocked by the workpiece holder surfaces securing the substrate.

Holders for wet semiconductor processing of rectangular workpieces may contact and/or constrain two, three or four edges of the workpiece, and for vertical processing typically there is contact on both front and back faces of the workpiece. For some applications a complete perimeter seal is advantageous as it prevents plating bath from contacting the edges of the workpiece, which can lead to areas of unwanted plating.

FIG. 1 schematically shows a known electroplating tool 50 capable of utilizing the frame holder and the loader/unloader apparatus of the present invention. Electroplating tool 50 is described in U.S. Pat. No. 11,887,874 and incorporated herein by reference. Electroplating tool 50 comprises an input/output module 51, a loader/unloader module 52, workpiece holder storage module 53, process modules 54-58, close patterning shield storage module 59, transporter support area 65, maintenance support area 66, electrical and chemical systems area 67, and a workpiece holder cleaning module 68. Tool 50 is a single-ended tool with unprocessed workpieces introduced into the tool and processed workpieces removed from the tool in the same input/output front-end module 51. Input/output front-end module 51 comprises one or more front opening unified pods (FOUP) and an equipment front end module (EFEM) robot which transports workpieces between input/output module 51 and loader/unloader module 52.

Although FIG. 1 shows five process modules 54-58, tool 50 may have any number of process modules depending on the exact process to be performed, such as the number of different metals to be electroplated, the number of pre-and post-plating processes and the number of duplicate modules used in parallel to increase tool throughput.

Workpiece holder storage module 53 is used to store workpiece holders when they are not in use. A local transporter (not shown) transfers workpiece holders from storage area 53 to loader/unloader 52 to bring them into service. Transporter support area 65 provides mechanical, electrical and fluid support to two or more transporters which overhang loader/unloader 52, process modules 54-58 and CPS storage area 59. Electrical and chemical systems area 67 house power distribution systems and fluid handling systems for all other modules. Maintenance support area 66 allows support personnel access to equipment in the electrical and chemical systems area 67 and to all electrical and fluid connections in the process modules 54-58. Workpiece holder cleaning module 68 comprises equipment for cleaning the workpiece holders when they are not being used for processing workpieces.

The processing flow for an unprocessed workpiece in tool 50 begins with its transfer, by a front end loading robot (not shown), from the input/output module 51 to the loader/unloader module 52 where the workpiece 60 (not shown) is loaded into a workpiece holder. The loaded workpiece holder is then transported using a transportation mechanism to a series of preprocessing modules 54-55 for wet processing steps such as pre-cleaning, pre-rinsing, and chemical activation. The loaded workpiece holder is then transported to either of process modules 56 or 57 for electroplating. After electroplating, the loaded workpiece holder 100 is transported to process module 58 for further processing steps such as final rinsing and drying. Following final rinsing and drying, the loaded workpiece holder is transported to the loader/unloader module 52 where the workpiece is unloaded from the workpiece holder. The processed workpiece is then transferred to the input/output module 51 for storage in a FOUP (not shown) until all the workpieces in the current batch have been processed.

Known workpiece holders with perimeter sealing have various limitations addressed by the present invention. The front frames of such known four-sided frame holders may be too thick to allow placement of either electric field uniformity shields or fluid agitation plates sufficiently close to the workpiece. Close positioning shields, which include patterns of apertures which correspond to target positions on the workpiece as described in U.S. Pat. No. 11,608,563, are used in electroplating to improve the uniformity of features plated on the workpiece. Agitation plates are used to increase plating, stripping or etching rates by uniformly increasing the transport of processing chemistry constituents to the workpiece face. Close positioning shields and agitation plates both need to be placed within a few millimeters of the workpiece, which has not been possible using known four-sided frame holders.

There is a need for a compact workpiece holder which allows processing of both faces of a workpiece while allowing a shield or agitation plate to be positioned close to the faces of the workpiece. There is a need for such a workpiece holder to have a reliable internal locking mechanism without relying on external facilities such as vacuum clamping, and for such a holder to independently set the sealing and electrical contact forces between the holder and the workpiece.

### SUMMARY OF THE INVENTION

In accordance with a first aspect of the invention there is provided a workpiece holder for holding a substantially planar, quadrilateral workpiece in a processing chamber of a wet semiconductor processing system, the workpiece holder being adapted for insertion into and removal from the processing chamber while holding the workpiece,
wherein the workpiece holder comprises:
   a support frame,
   first and second perimeter sealing plates attached to the support frame, each of the first and second perimeter sealing plates having respective interlocking features attached thereto,
   a locking plate, the locking plate being moveable relative to the support frame between a locked configuration in which the locking plate engages with the interlocking features of both the first and second perimeter sealing plates, and an open configuration in which the locking is disengaged therefrom, wherein in the open configuration the first and second perimeter sealing plates may be separated sufficiently to allow the workpiece to be inserted therebetween, and in the locked configuration the workpiece is clamped relative to the support frame, and
   wherein each of the first and second perimeter sealing plates comprises a flexure biased to provide sealing force to the workpiece when the locking plate is in the locked configuration.

In accordance with a second aspect of the present invention there is provided a semiconductor processing system for processing a substantially planar, quadrilateral workpiece while loaded into the workpiece holder of the first aspect, the system comprising:
a processing chamber for wet chemical etch, cleaning or electrodeposition, and
a workpiece loader for loading the workpiece into the workpiece holder during a loading operation.

Other specific aspects and features of the present invention are set out in the accompanying claims.

### BRIEF DESCRIPTION OF THE DRAWINGS

The invention will now be described with reference to the accompanying drawings (not to scale), in which:

FIG. 1 schematically shows a known electrochemical deposition tool;

FIG. 2 schematically shows, from the front, a workpiece holder and workpiece;

FIG. 3 schematically shows, from the front, details of the workpiece holder;

FIG. 4 schematically shows, from the front, details of the workpiece holder;

FIG. 5 schematically shows, from the front, details of a workpiece holder locking assembly;

FIG. 6A schematically shows, from the front, details of a workpiece holder locking plate;

FIG. 6B schematically shows, from the front, details of the workpiece holder locking plate;

FIG. 7A schematically shows, from the side, a cross section of the workpiece holder in a clamped position;

FIG. 7B schematically shows, in isometric view, the workpiece holder in a clamped position;

FIG. 8 schematically shows, in isometric view, a portion of the workpiece holder and a flexible perimeter sealing plate;

FIG. 9A schematically shows, from the front, a portion of the workpiece holder locking plate and locking assembly in an unlocked configuration;

FIG. 9B schematically shows, from the front, a portion of the workpiece holder locking plate and locking assembly in a locked configuration;

FIG. 10A schematically shows, from the front, a portion of the workpiece holder locking plate and locking assembly in an unlocked configuration;

FIG. 10B schematically shows, from the front, a portion of the workpiece holder locking plate and locking assembly in a locked configuration;

FIG. 11 schematically shows, in isometric view, a loading system for a workpiece holder;

FIG. 12 schematically shows, in isometric view, a cross section of the loading system;

FIG. 13 schematically shows, in isometric view, a portion of the loading system; and

FIG. 14 schematically shows, in isometric view, a portion of the loading system.

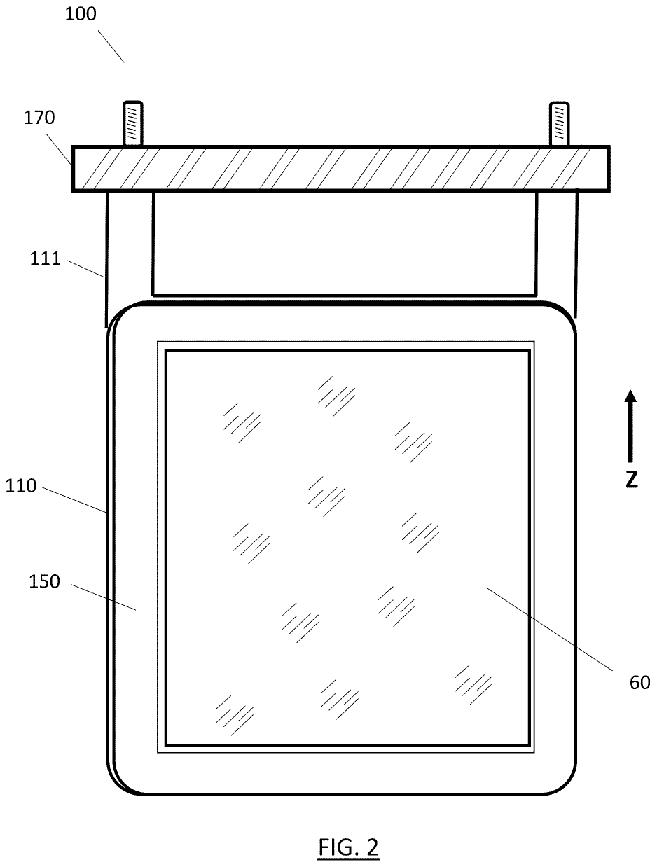

For consistency and clarity, like reference numerals will be retained for like components throughout the following description. FIGS. 2-4 are shown with nominal cartesian axis Z fixed with respect to the workpiece to indicate the vertical direction. The following description will use the term “workpiece” to refer to any item suitable for wet chemical semiconductor processing, including semiconductor wafers, substrates and panels and the like, as is generally known in the art.

### DETAILED DESCRIPTION

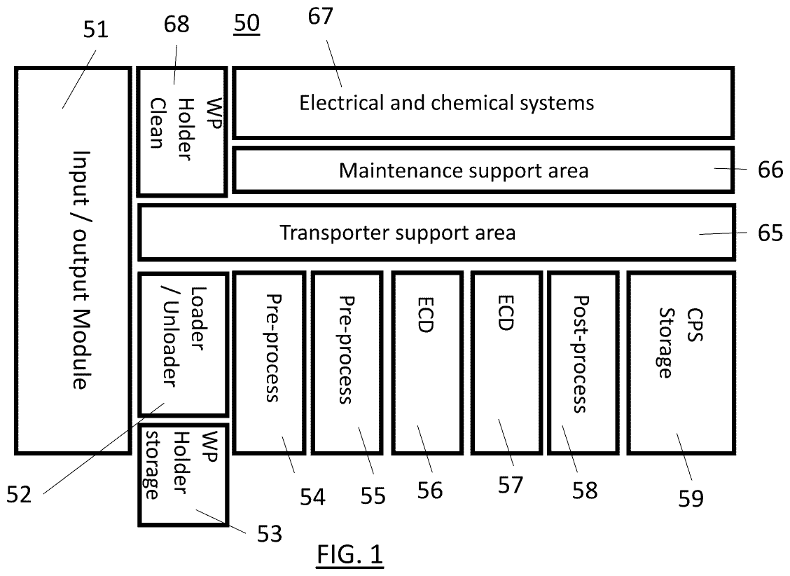

FIG. 2 shows a workpiece holder 100 which workpiece holder 100 may be used with an electrochemical deposition tool such as that shown in FIG. 1. The workpiece holder 100 comprises a central support frame 110 having an extension 111, first and second perimeter sealing plates 150, 150′ (only the frontmost sealing plate 150 being visible in FIG. 2; this will hereafter be referred to as the “front perimeter sealing plate” or “front PSP”), and a transport handle 170, attached to the extension 111. A workpiece 60 is shown in a clamped position after loading into the workpiece holder 100 by the loader/unloader module 52. The transport handle 170 is adapted so that it may be used to pick up the workpiece holder 100 in the loader/unloader module 52 by an overhead transporter for transport to pre-process modules 54 and 55, and subsequently to at least one process modules 56-58 before returning to the loader/unloader module 52 for unloading. Each perimeter sealing plate 150 is substantially rectangular, having a window formed in a central region thereof to permit chemistry access to the workpiece 60 in use, while covering an external periphery of the workpiece 60.

The perimeter seal plates 150, 150′ and the central support frame 110, extension 111 and transport handle 170 may for example be fabricated from stainless steel over-molded and/or coated with an FKM material, a fluorinated polymer such as Viton®, polytetrafluoroethylene or ethylene chlorotrifluoroethylene. Alternately, these components may be fabricated from a polymer such as polyether ether ketone. Perimeter seal plates 150, 150′ are each fabricated as a flexure, of shape, dimensions and material chosen to provide a known force when constrained in a closed, clamped position.

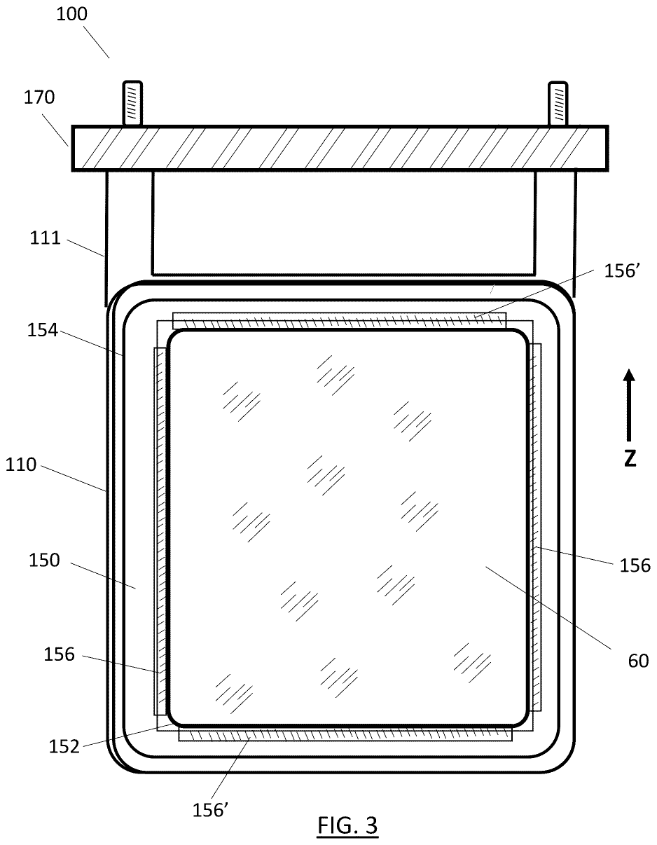

FIG. 3 shows workpiece holder 100 including internal details of front perimeter sealing plate (PSP) 150. As shown, front PSP 150 is separably connected to internal contact plates (ICPs) 156 at each lateral side as well as top and bottom ICPs 156′, inner seal 152 and outer seal 154, with all of these also being separably connected to the rear PSP 150′, so that there are located between the front and rear PSPs 150, 150′. This arrangement enables four-sided electrical contact with the workpiece 60 via the ICPs 156, 156′. In an alternative embodiment (not shown) which utilizes only two-sided electrical contact, PSP 150 would comprise only side ICPs 156, omitting the top and bottom ICPs 156′. In a preferred embodiment, inner seal 152 and outer seal 154 are incorporated into PSP 150 during polymer over-molding. In an alternate embodiment, seals 152 and 154 may comprise removable and/or replaceable polymer O-rings.

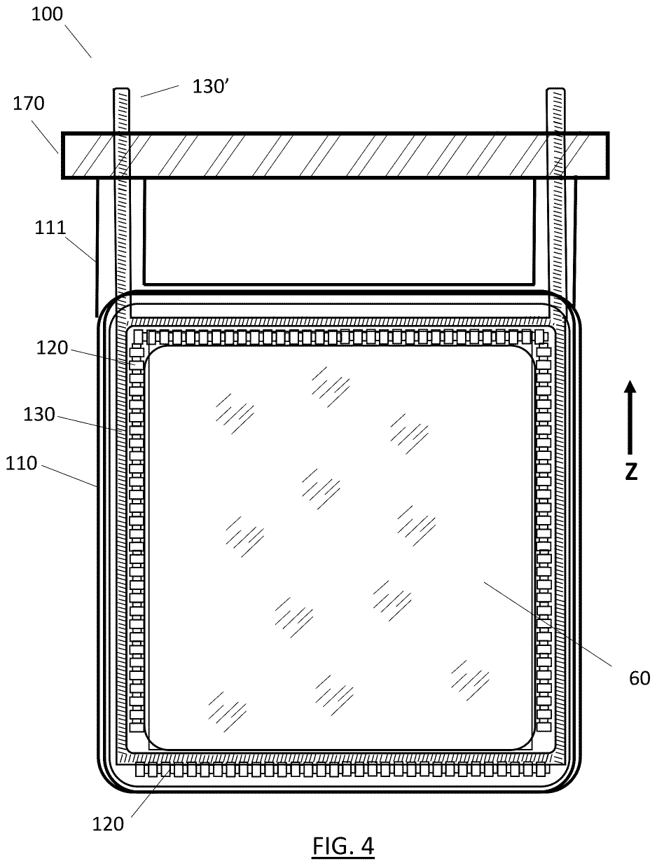

FIG. 4 shows the workpiece holder 100 with the frontmost PSP 150 removed to reveal internal features. These include a front locking assembly 120 and a locking plate 130. Locking plate 130 is capable of sliding vertically, in the direction indicated by the Z axis, with respect to center support frame 110. A portion 130′ of locking plate 130 passes through extension 111, extending past transport handle 170. Locking plate 130 may for example be fabricated from stainless steel or another metallic conductor. Locking plate 130 may be used as an electrical bus, when a contact (not shown) is activated to electrically connect an external power supply (also not shown) to the locking plate portion 130′ when workpiece holder 100 is inserted into an ECD process module 56, 57.

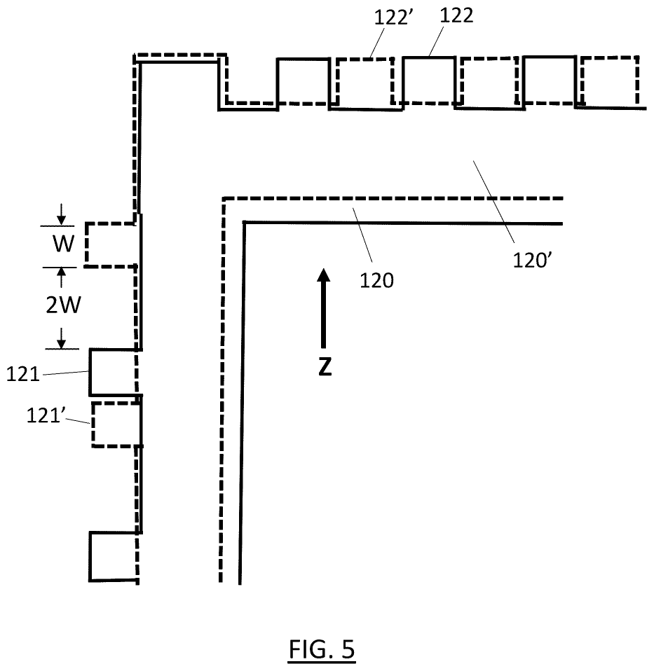

FIG. 5 shows more details of the locking assembly, which comprises the front locking assembly 120 and a rear locking assembly 120′. In FIG. 5, these are shown superimposed. The front and rear locking assemblies 120 and 120′ are crenellated and so respectively comprise interlocking features including alternating side interlock features in the form of extensions/crenellations 121 and 121′ and top and bottom extensions/crenellations 122 and 122′ which may slide past each other in a direction perpendicular to the vertical Z axis and normal to the plane of the page, when the front PCP 150 and rear PCP 150′ are in their clamped position. The width of the interlock extensions 121 and 121′ are shown in FIG. 5 as ‘W’, and the gap between adjacent interlock extensions may be 2W, where W may for example be in the range of 5 to 25 mm.

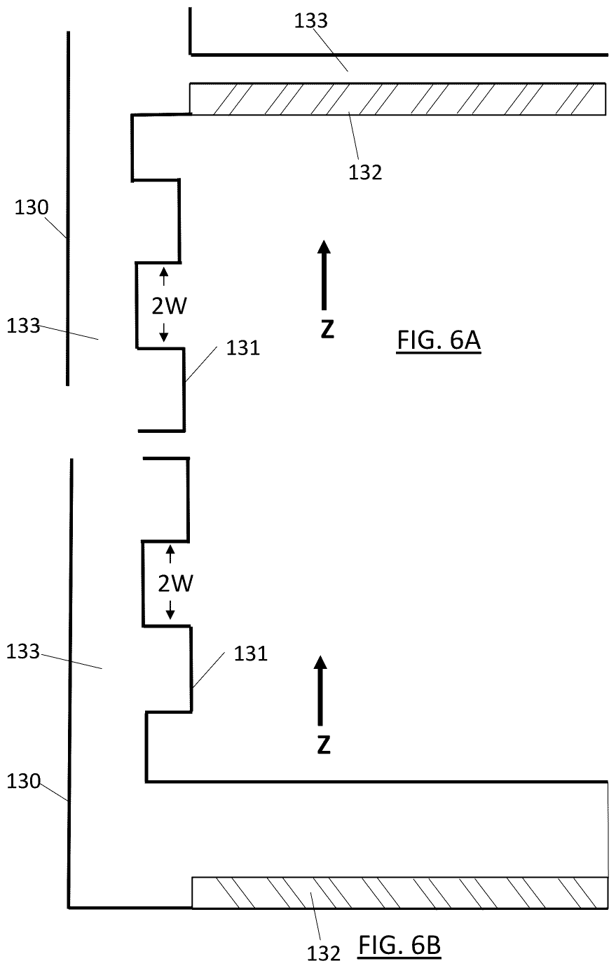

FIGS. 6A and 6B respectively shows details of locking plate 130 at its top and bottom left corners. Locking plate 130 comprises main support 133, with crenellated sides having side extension fingers/crenellations 131, and top and bottom extensions 132. The side extension fingers 131 are repeating projections of a width which is sufficiently small to permit them to slide between corresponding projections in interlock extensions 121 and 121′ in a direction normal to the plane of the page. The top and bottom extensions 132 are formed as plates, having a sufficiently small thickness to allow their insertion between the top and bottom interlock extensions 122 and 122′. The width of each side extension finger 131 and the gap between adjacent side extension fingers 131 are shown as 2W, and thereby sized to interlock with the interlock extensions 121 and 121′ shown in FIG. 5.

While the interlocking extensions 121, 121′, 122, 122′, as well as the projections of the locking plate extension fingers 131 are all shown as being of rectangular form, the invention is not so limited, and various shapes may be used, such, for example only, triangular features/projections.

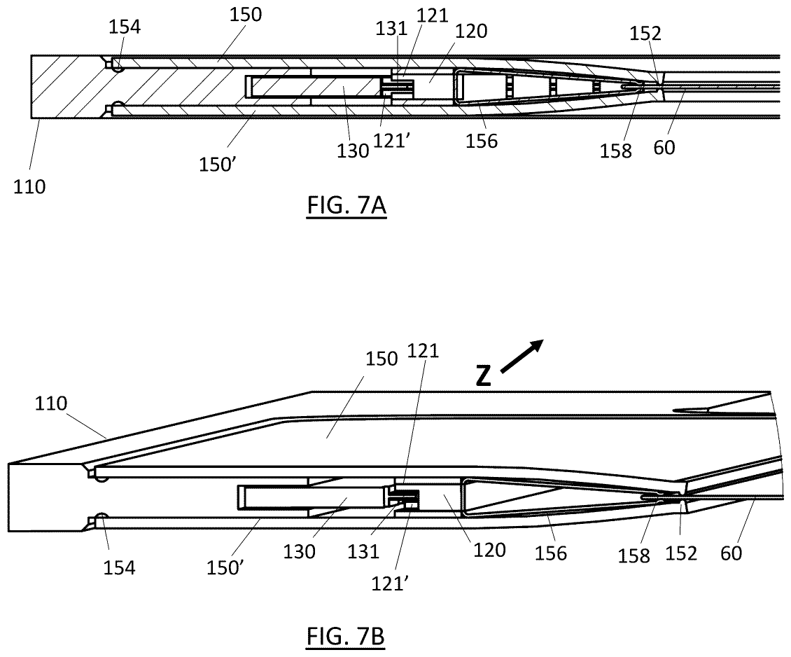

FIGS. 7A and 7B show cross-section and isometric views of the workpiece holder 100 with its two perimeter sealing plates 150 (“front PSP”) and 150′ (“rear PSP”) holding the workpiece 60 in a clamped position. In these figures it can be seen that each of the front and rear PCPs 150, 150′ effectively functions as a leaf spring, with its internal edge, at which inner seal 152 is formed, biased towards the central plane of the workpiece holder 100 (i.e. the plane which is co-planar with the workpiece 60), but capable of being flexed away from this plane. Each of the front PCP 150 and rear PCP 150′ applies clamping force to the workpiece holder 100 at a respective inner seal 152. Each of the front PCP 150 and the rear PCP 150′ also applies sealing force to center support frame 110 at a respective outer seal 154. Front and rear PCPs 150, 150′ compress the ICP 156 in order to make electrical contact with the workpiece 60 at an ICP contact 158. ICP 156 and ICP contact 158 may be fabricated as a welded assembly with PCPs 150 and 150′. Alternatively, they may be bolted to PCPs 150 and 150′ and thereby removable. Locking plate 130 may be in electrical contact with ICP 156 and ICP contact 158 using a flexible strap (not shown). Locking plate 130 is positioned such that locking plate extension fingers 131, which extend from the locking plate 130 towards the center of the workpiece holder 100, are inserted into locking assembly 120, securing rear PCP 150′ to front PCP 150 in a locked, clamped position.

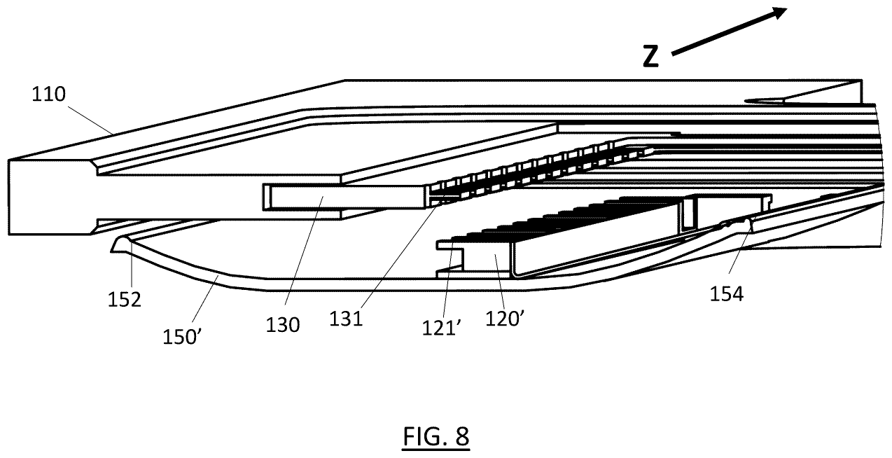

FIG. 8 shows an isometric view of a side portion of the workpiece holder 100 with the rear PCP 150′ shown in an unclamped, open configuration, while the front PCP 150 is omitted for clarity. The central support frame 110, locking plate 130, and locking plate extension fingers 131 are all visible. Also shown are the inner seal 152, outer seal 154, locking assembly 120′ and locking extension 121 of ‘the rear PCP 150’. Prior to clamping, locking plate extension fingers 131 slide vertically between corresponding interlock extensions 121′ as pressure is applied to PCP 150′, as will be described in more detail below.

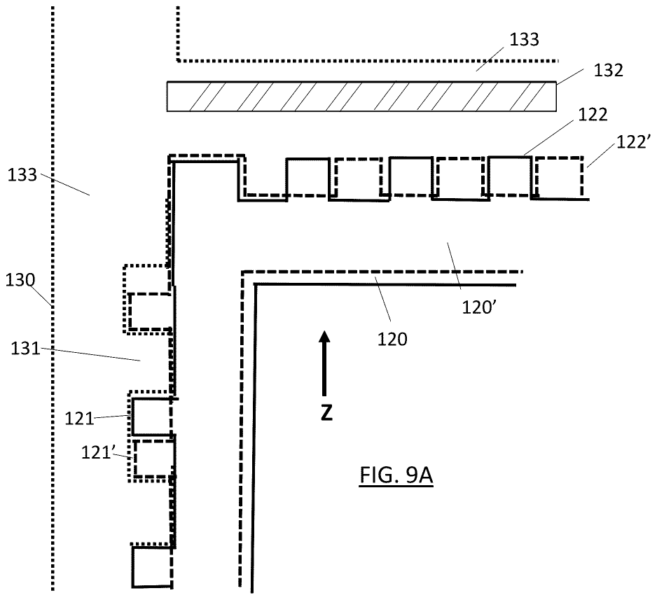

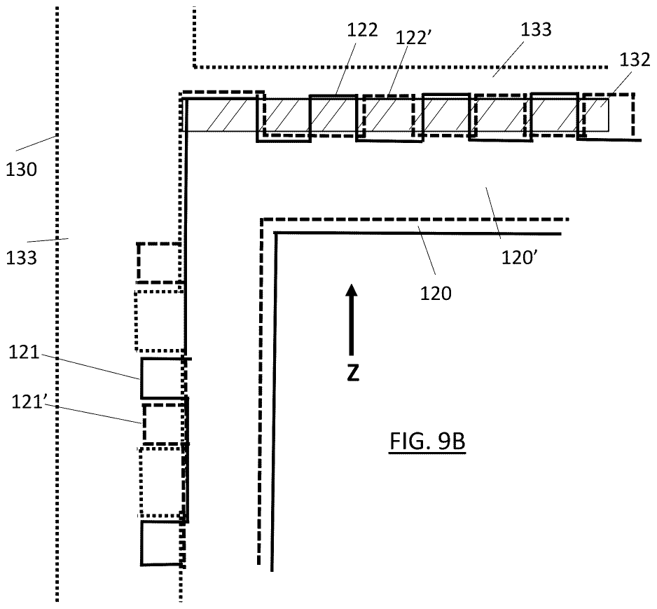

FIGS. 9A and 9B respectively show relative orientations of the top left corner of the locking plate 130, the front locking assembly 120 and the rear locking assembly 120′ before and after locking. As shown in FIG. 9A, prior to locking, the top extension 132 is above the locking assembly top interlock extensions 122 and 122′ and in an orientation which allows side interlock extensions 121 and 121′ to slide past side extension fingers 131. During locking, locking plate 130 slides vertically downwards, inserting top extensions 132 between top extensions 122 and 122′ and side extension fingers 131 between side interlock extensions 121′ and 121.

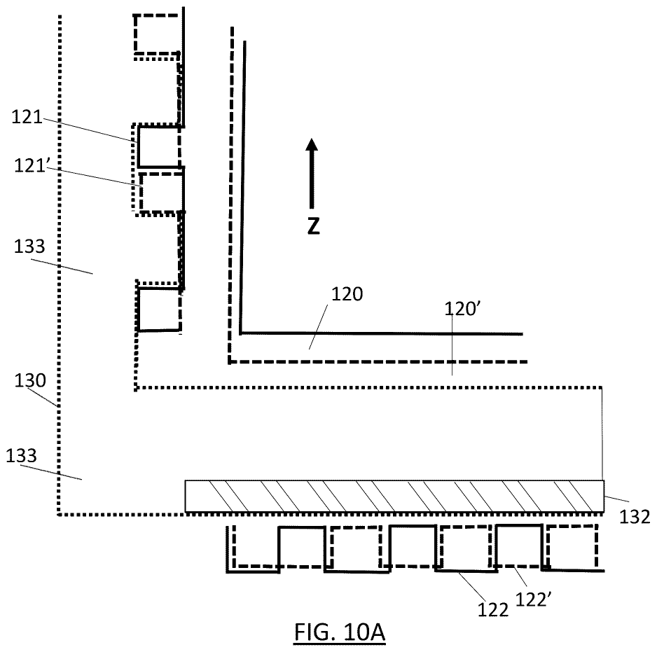

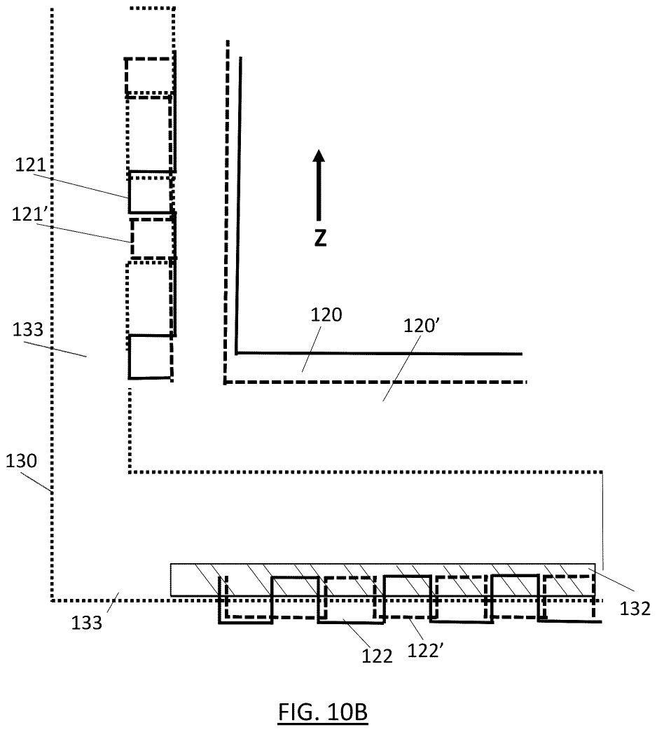

FIGS. 10A and 10B respectively show relative orientations of the bottom left corner of the locking plate 130, the front locking assembly 120 and the rear locking assembly 120′ before and after locking. As shown in FIG. 10A, prior to locking, the bottom extension 132 is above the locking assembly bottom extensions 122 and 122′ and in an orientation which allows side interlock extensions 121 and 121′ to slide past side extension fingers 131. During locking, locking plate 130 slides vertically downwards, inserting bottom extensions 132 between bottom extensions 122 and 122′ and side extension fingers 131 between side interlock extensions 121′ and 121.

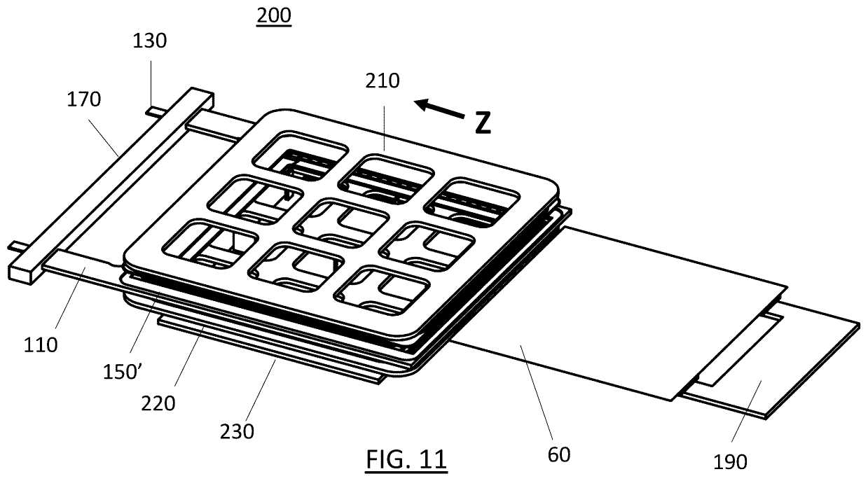

FIG. 11 shows an isometric drawing of a workpiece loader 200 for use with the workpiece holder 100, comprising an upper frame 210, lower frame 220, and loader support frame 230. The workpiece loader 200 is shown in a first, horizontal, configuration in which the workpiece holder 100 may be inserted into the workpiece loader.

Also shown are a workpiece 60, which is quadrilateral and substantially planar, and an end effector 190 in a position prior to insertion of workpiece 60 into workpiece holder 100. At the commencement of a loading operation, a workpiece 60 may be aligned on end effector 190 prior to insertion, such that features of workpiece 60 are aligned, by an alignment system (not shown), with respect to the workpiece holder 100, more particularly with features on a close patterning shield (not shown in FIG. 7) when workpiece holder 100 is inserted into ECD process module 56, as described in U.S. Pat. No. 11,942,341.

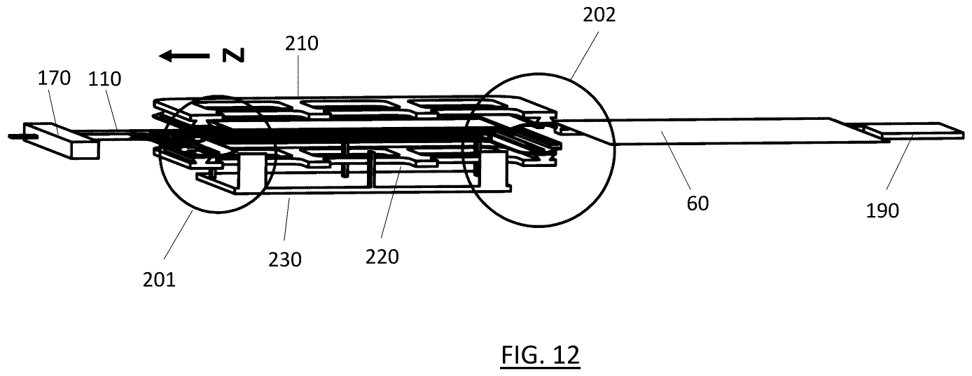

FIG. 12 shows an isometric drawing of the workpiece loader 200 for use with the workpiece holder 100, with callout areas 201 and 202. Callout area 201 is from the top portion of the workpiece holder 100. Callout area 202 is from the bottom portion of workpiece holder 100.

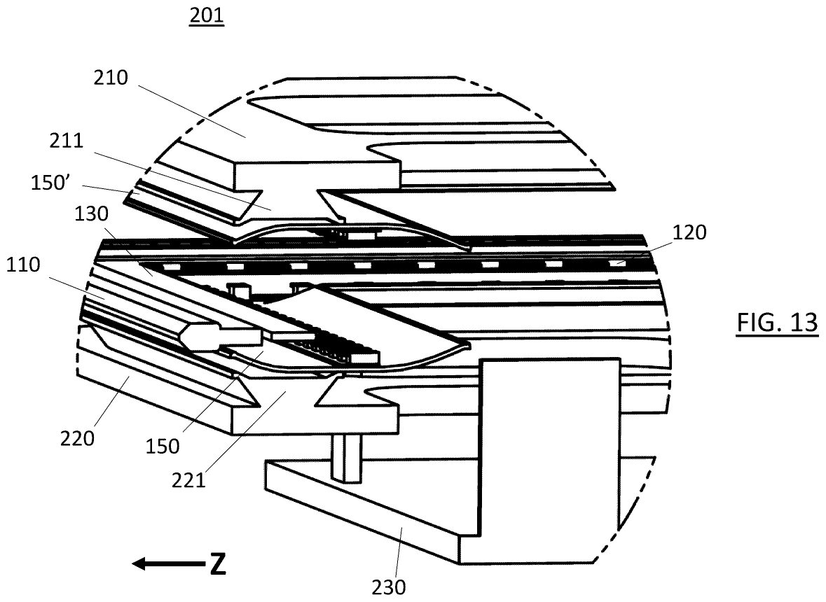

FIG. 13 shows details of callout area 201 from FIG. 12. Upper frame 210 comprises an upper vacuum chuck 211 shown gripping rear PCP 150′. Lower frame 220 comprises lower vacuum chuck 221 shown gripping front PCP 150. The loader support frame 230 may provide rigid support to lower frame 220. Alternately, loader support frame 230 may comprise an actuated lift assembly (not shown) for vertical translation of lower frame 220.

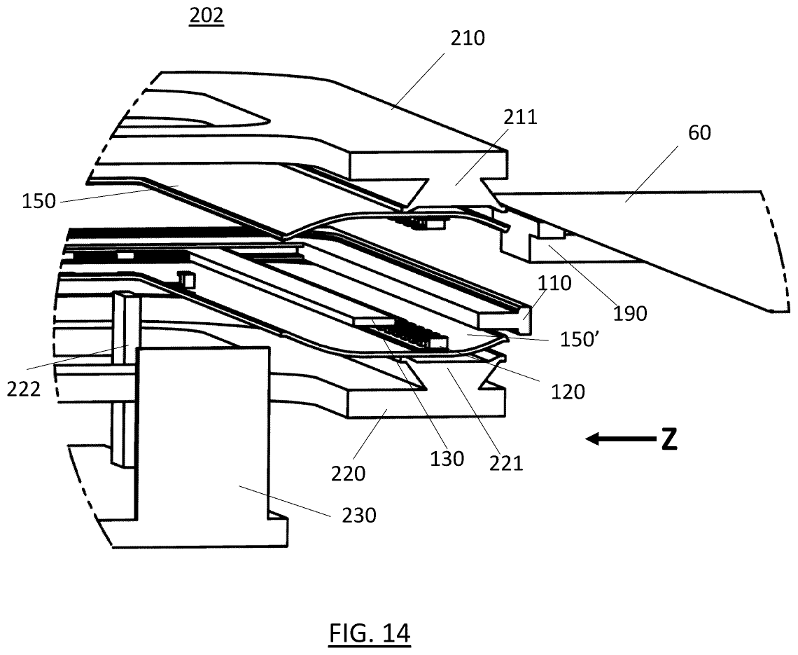

FIG. 14 shows details of callout area 202 from FIG. 12, for assisting in the following discussion of the loading operation. Prior to or during the loading operation, the upper frame 210 is raised upwards by a mechanical or pneumatic assembly (not shown) such that the gap between rear PCP 150′ and central support frame 110 is made sufficient to allow passage of workpiece 60 and end effector 190 therethrough. During loading, end effector 190 lowers, placing workpiece 60 onto a vertical stage 222 supported on lower frame 230. End effector 190 then withdraws. Stage 222 is then lowered by a mechanical or pneumatic assembly (not shown), which places workpiece 60 onto rear PCP 150′. Upper support frame 210 is then lowered, compressing both the rear PSP 150′ and front PCP 150. The upper and lower vacuum chucks 211, 221 are configured to provide sufficient force to the front and rear PSPs 150, 150′ so that the locking plate 130 can be inserted between the interlocking features 121, 121′, 122, 122′ of the PSPs 150, 150′. An activation system comprising an actuator (not shown) then slides the locking plate 130 between locking assemblies 120 and 120′, thereby locking workpiece holder 100 in this compressed state. The workpiece loader 200 may now be rotated, by a rotation actuator (not shown), from this first substantially horizontal orientation to a second, substantially vertical, orientation to allow overhead transporter to pick up and transport the workpiece holder 100 to pre-process module 54 and subsequent process modules.

1. A workpiece holder for holding a substantially planar, quadrilateral workpiece in a processing chamber of a wet or semiconductor processing system, the workpiece holder being adapted for insertion into and removal from the processing chamber while holding the workpiece,
wherein the workpiece holder comprises:
a support frame,
first and second perimeter sealing plates attached to the support frame, each of the first and second perimeter sealing plates having respective interlocking features attached thereto, and
a locking plate, the locking plate being moveable relative to the support frame between a locked configuration in which the locking plate engages with the interlocking features of both the first and second perimeter sealing plates, and an open configuration in which the locking is disengaged therefrom, wherein in the open configuration the first and second perimeter sealing plates may be separated sufficiently to allow the workpiece to be inserted therebetween, and in the locked configuration the workpiece is clamped relative to the support frame, and
wherein each of the first and second perimeter sealing plates comprises a flexure biased to provide sealing force to the workpiece when the locking plate is in the locked configuration.

2. The workpiece holder of claim 1, comprising a plurality of internal contact plates located between the first and second perimeter sealing plates,
the internal contact plates providing electrical contact to the workpiece when the locking plate is in the locked configuration.

3. The workpiece holder of claim 2, in which the locking plate is in electrical connection to the internal contact plates.

4. The workpiece holder of claim 1, where the first and second perimeter sealing plates are fabricated from stainless steel coated with a fluorinated polymer selected from the group comprising FKM materials, Viton®, polytetrafluoroethylene and ethylene chlorotrifluoroethylene.

5. The workpiece holder of claim 1, where the first and second perimeter sealing plates are fabricated from a polymer, optionally the polymer comprises polyether ether ketone.

6. The workpiece holder of claim 2, where the internal contact plates are separable from the first and second perimeter sealing plates.

7. A semiconductor processing system for processing a substantially planar, quadrilateral workpiece while loaded into the workpiece holder of claim 1, the system comprising:
a processing chamber for wet chemical etch, cleaning or electrodeposition, and
a workpiece loader for loading the workpiece into the workpiece holder during a loading operation.

8. The semiconductor processing system of claim 7, wherein the workpiece loader comprises:
first and second chucks,
an end effector, and
an activation system for sliding the locking plate between the locked and open configurations;
wherein the first and second chucks are configured to grip the first and second perimeter sealing plates, separating them sufficiently so that the end effector and workpiece may be inserted into the workpiece holder; and
wherein the first and second chucks are configured to provide sufficient force to the first and second perimeter sealing plates so that the locking plate can be inserted between the interlocking features.

9. The semiconductor processing system of claim 9, wherein the workpiece loader comprises an alignment system for aligning the workpiece with respect to the workpiece holder prior to inserting the workpiece into the workpiece holder.

10. The semiconductor processing system of claim 9, wherein the workpiece loader comprises a rotation actuator for rotating the workpiece holder between a substantially horizontal configuration and a substantially vertical configuration.
